(19) United States
(12) Patent Application Publication
(10) Pub. No.: US 2018/0074134 A1
(43) Pub. Date: Mar. 15, 2018

(54) BATTERY PACK MONITOR

(71) Applicant: Gregory P. Leopold, Victoria, TX (US)

(72) Inventor: Gregory P. Leopold, Victoria, TX (US)

(21) Appl. No.: 15/700,441

(22) Filed: Sep. 11, 2017

Related U.S. Application Data
(60) Provisional application No. 62/385,349, filed on Sep. 9, 2016.

(51) Int. Cl. G01R 31/36; H01M 10/42

(52) U.S. Cl. CPC G01R 31/3682; H01M 2220/20; G01R 31/3658; H01M 10/4285

(57) ABSTRACT

A battery pack monitor a method of use for simultaneously deterring the voltage of a battery pack and the individual batteries that make up the battery pack.

### CROSS-REFERENCE TO RELATED APPLICATIONS

This application claims priority to the U.S. Provisional Patent Application No. 62/385,349, filed Sep. 9, 2016, and is hereby incorporated by reference in its entirety.

### FIELD OF THE INVENTION

The present disclosure relates to a voltage meter. More specifically, the disclosure relates to a voltage meter for measuring the voltage of a battery pack.

### BACKGROUND OF THE INVENTION

Generally, in modern electrical vehicles, such as electric golf carts, a series of batteries are used to supply power for the vehicle. Businesses that operate or repair electrical vehicles must regularly check the voltage of the batteries in the electrical vehicles to determine if the vehicle must be recharged before it is used again.

Presently, the common method of assessing battery condition is to connect a voltage meter to the terminals of the battery, and to observe terminal voltage as a function of time while the battery discharges. For electrical vehicles that have a series of batteries, this process involves multiple stages. The operator of the voltage meter must connect the voltage meter to one battery, check the voltage, disconnect the connection wires, then connect the wires to the next battery. In addition to checking each individual battery, the operator must also check the voltage of the series of batteries by connecting the voltage meter to the first and last battery in the series. A problem with checking each battery and the series separately is that the results can be forgotten if not written down. Comparing the results from individual batteries and the series can help inform the operator if there is a problem with any specific battery.

The multi-step process of checking a series of batteries can be very time consuming and inefficient. When the cost of maintaining an electric vehicle is primarily impacted by the cost of labor per hour, a more efficient method for performing repetitive tasks is needed.

### BRIEF SUMMARY

In accordance with the present inventive subject matter, a portable instrument is disclosed for measuring the voltage of a battery pack and the individual batteries that make up the battery pack. The advantage of the disclosed inventive subject matter is the ability to see the voltage of all component batteries of the battery pack at the same time. This allows for a more efficient determination if any of the batteries of the battery pack have defects.

The novel features that are considered characteristic of the disclosure subject matter are set forth with particularity in the appended claims. The disclosure subject matter will best be understood from the following description when read in connection with the accompanying drawings.

### BRIEF DESCRIPTION OF THE DRAWINGS

The present subject matter will now be described in detail with reference to the drawings, which are provided as illustrative examples of the subject matter so as to enable those skilled in the art to practice the subject matter. Notably, the FIGUREs and examples are not meant to limit the scope of the present subject matter to a single embodiment, but other embodiments are possible by way of interchange of some or all of the described or illustrated elements and, further, wherein:

FIG. 1 depicts a perspective view of a battery pack monitor.

FIG. 2 depicts an embodiment of a battery pack monitor connected to a battery pack.

FIG. 3 depicts an embodiment of a battery pack monitor connected to a single battery.

FIG. 4 depicts an embodiment of a connector used for connecting the battery pack monitor to a battery.

FIGS. 5 and 6 depict an embodiment of a wired connection.

FIG. 7 depicts an embodiment of the battery pack monitor connected to a golf cart battery pack.

### DETAILED DESCRIPTION OF ILLUSTRATIVE EMBODIMENTS

The detailed description set forth below in connection with the appended drawings is intended as a description of exemplary embodiments in which the presently disclosed process can be practiced. The term “exemplary” used throughout this description means “serving as an example, instance, or illustration,” and should not necessarily be construed as preferred or advantageous over other embodiments. The detailed description includes specific details for providing a thorough understanding of the presently disclosed method and system. However, it will be apparent to those skilled in the art that the presently disclosed process may be practiced without these specific details. In some instances, well-known structures and devices are shown in block diagram form in order to avoid obscuring the concepts of the presently disclosed method and system.

In the present specification, an embodiment showing a singular component should not be considered limiting. Rather, the subject matter preferably encompasses other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present subject matter encompasses present and future known equivalents to the known components referred to herein by way of illustration.

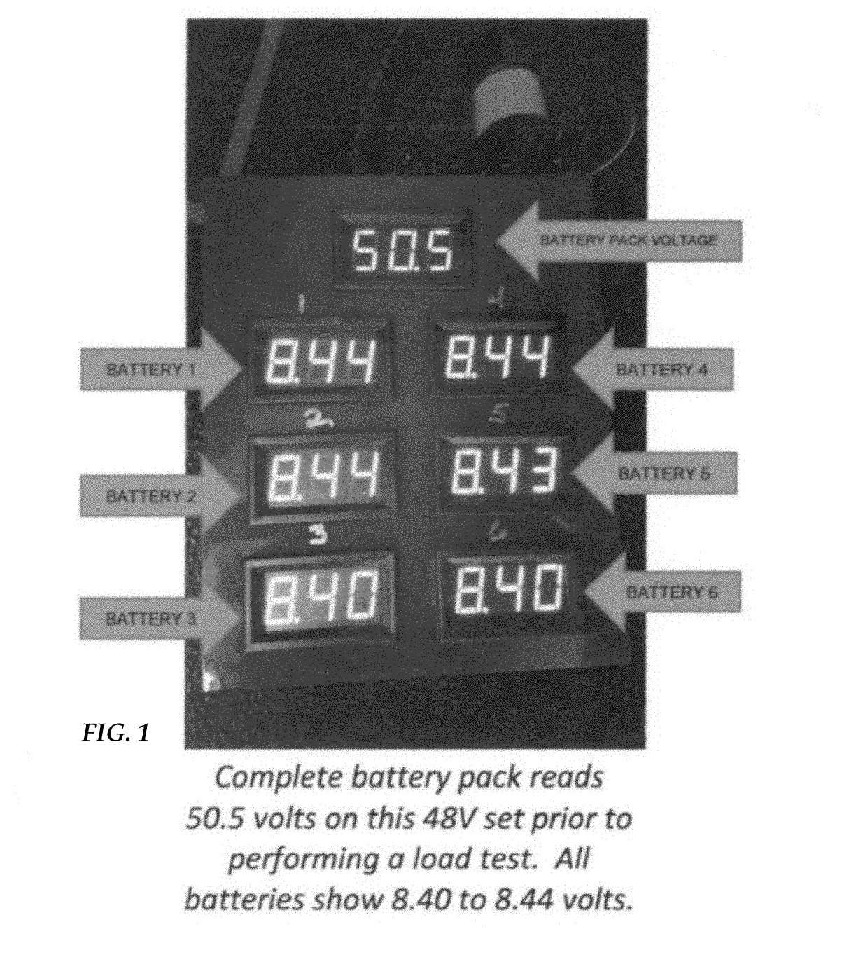

FIG. 1 depicts a perspective view of a battery pack monitor. The figure illustrates a battery pack monitor with a display panel, a wired connection, a main voltage, a plurality of voltage displays. This allows for quick reading of each voltage for each battery and to quickly see the voltage of the entire battery pack. The wired connection organizes the lines that electrically connect each voltage display to its associated battery. The wired connection connects to a output-input port. The physical connection of the wired connection and the output-input port enable the electrical connection of the voltage displays to the batteries.

The voltage displays comprise a display and a voltage meter. The voltage meter and voltage display are electrically connected. The connected display may be either analog or digital.

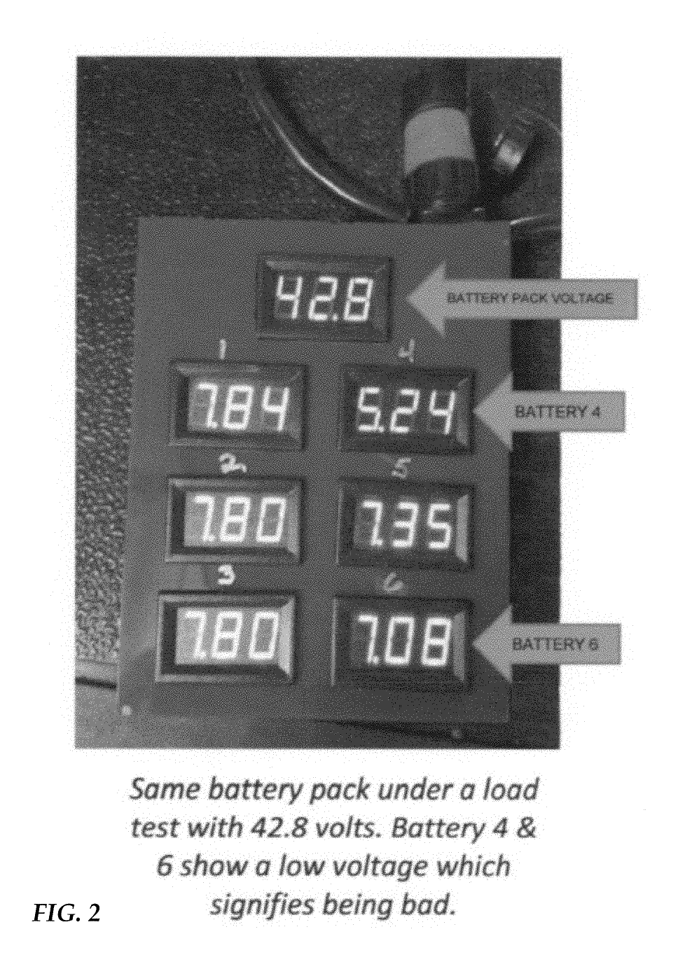

FIG. 2 depicts an embodiment of a battery pack monitor connected to a battery pack. The illustration shows a wired connection between the positive end of a first voltage display to a negative end of a first battery of a battery pack. A wired connection between the negative end of the first voltage display to a positive end of the first battery of a battery pack. A wired connection between the positive end of a second voltage display to a negative end of a second battery of a battery pack. A wired connection between the negative end of a second voltage display to a positive end of a second battery of the battery pack. Electrically connecting the negative end of the first battery to the positive end of the second battery.

A wired connection between the positive end of a third voltage display to a negative end of a third battery of a battery pack. A wired connection between the negative end of a third voltage display to a positive end of a third battery of the battery pack. Electrically connecting the negative end of the second battery to the positive end of the third battery.

A wired connection between the positive end of a fourth voltage display to a negative end of a fourth battery of a battery pack. A wired connection between the negative end of a fourth voltage display to a positive end of a fourth battery of the battery pack. Electrically connecting the negative end of the third battery to the positive end of the fourth battery.

A wired connection between the positive end of a fifth voltage display to a negative end of a fifth battery of a battery pack. A wired connection between the negative end of a fifth voltage display to a positive end of a fifth battery of the battery pack. Electrically connecting the negative end of the fourth battery to the positive end of the fifth battery.

A wired connection between the positive end of a sixth voltage display to a negative end of a sixth battery of a battery pack. A wired connection between the negative end of a sixth voltage display to a positive end of a sixth battery of the battery pack. Electrically connecting the negative end of the fifth battery to the positive end of the sixth battery.

Electrically connecting a negative end of a main voltage display to a positive end of the first battery of the battery pack, and electrically connecting a positive end of a main voltage display to a negative end of a sixth battery of a battery pack. Displaying the voltage of the first battery on the first voltage display. Displaying the voltage of the second battery on the second voltage display. Displaying the voltage of the third battery on the third voltage display. Displaying the voltage of the fourth battery on the fourth voltage display. Displaying the voltage of the fifth battery on the fifth voltage display. Displaying the voltage of the sixth battery on the sixth voltage display. Displaying the voltage of the battery pack on the main voltage display.

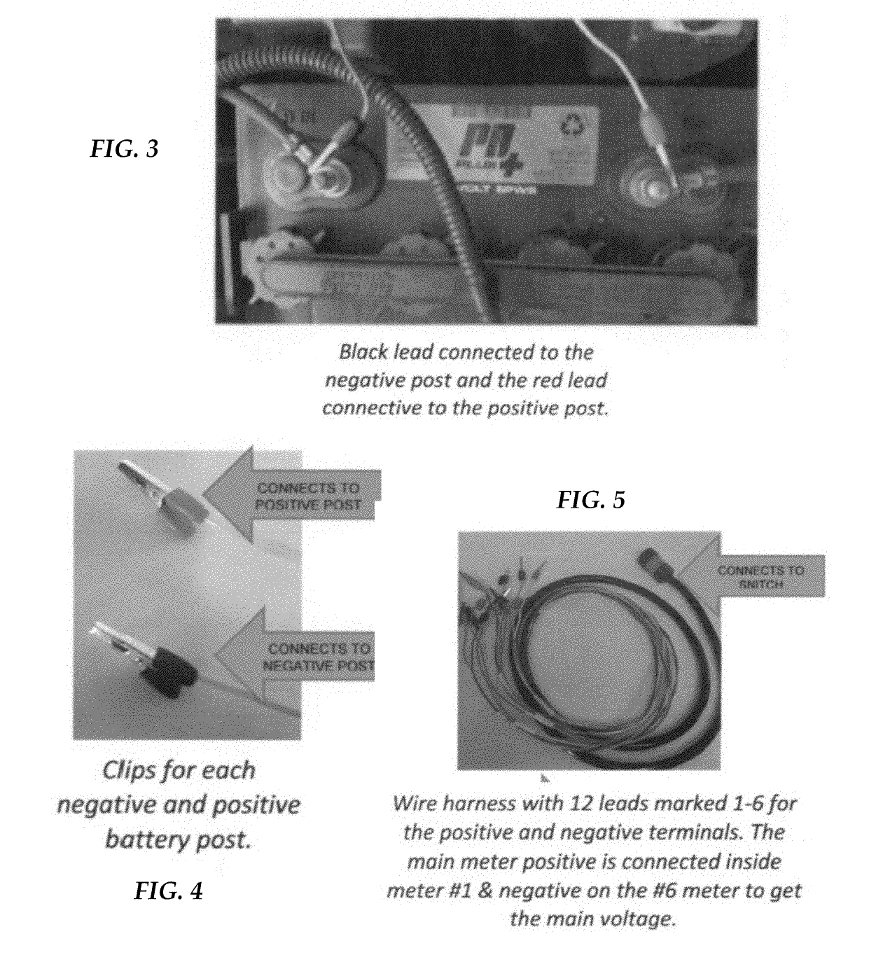

FIG. 3 depicts an embodiment of a battery pack monitor connected to a single battery. The illustration shows a wired connection between the positive end of a first voltage display to a negative end of a first battery. A wired connection between the negative end of the first voltage display to a positive end of the first battery of a battery pack.

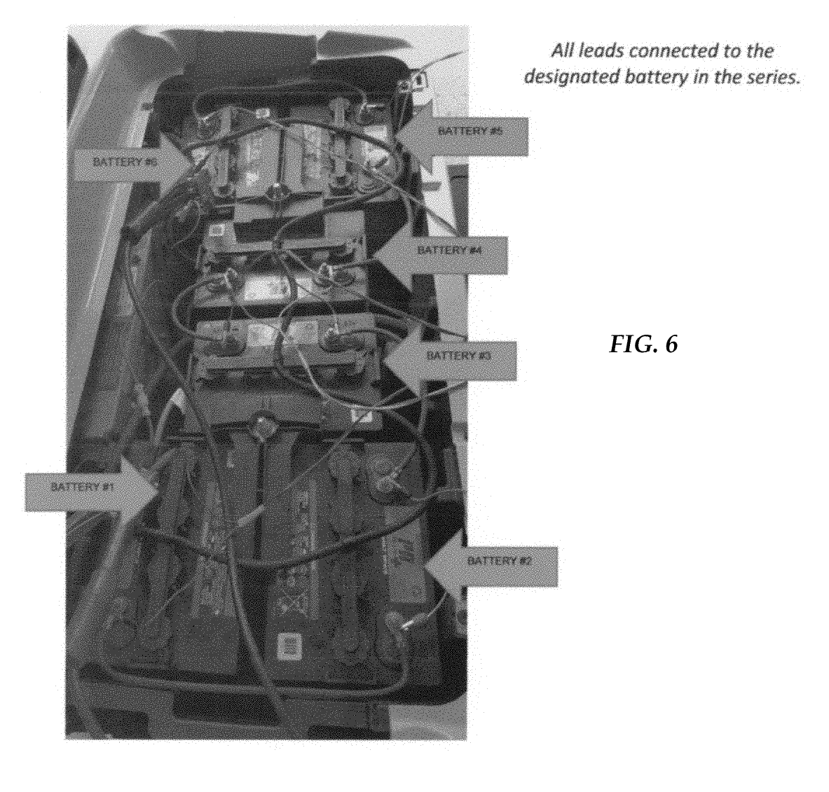

FIG. 4 depicts an embodiment of a wired connector clip used for connecting wired connection of the battery pack monitor to a battery. FIGS. 5 and 6 depicts an embodiment of a wired connection including the wired connector clip.

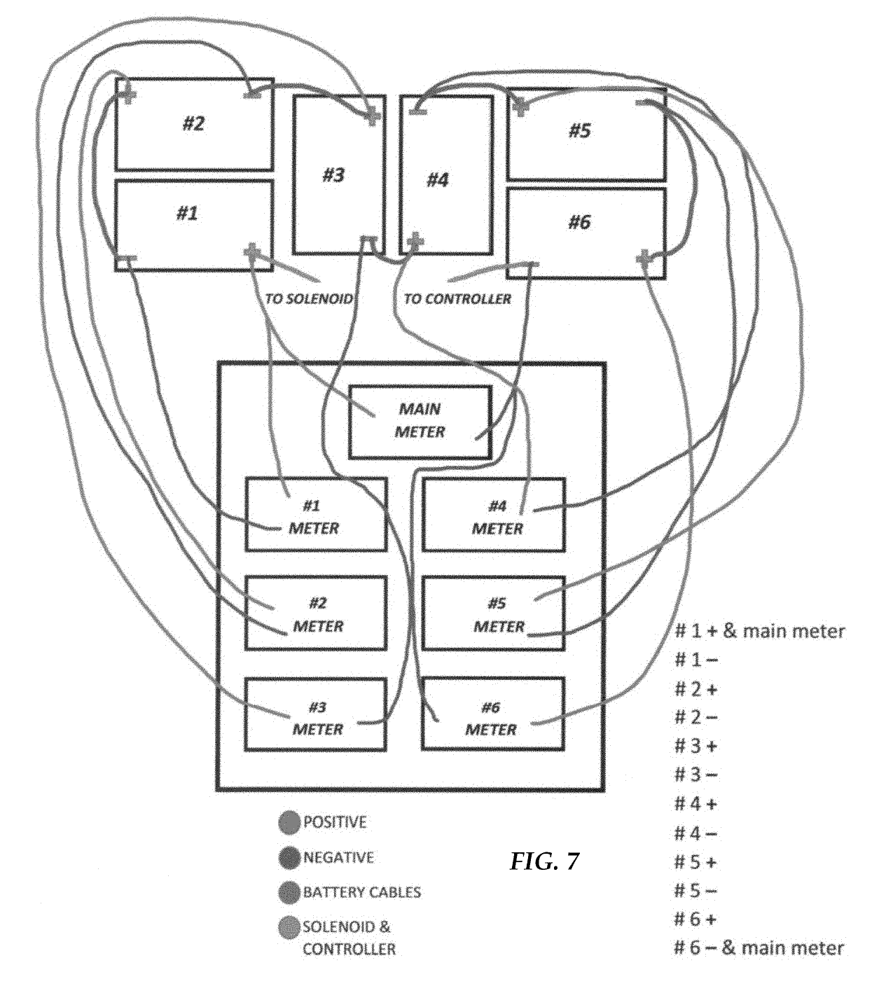

FIG. 7 depicts an embodiment of the battery pack monitor connected to a golf cart battery pack. A golf cart is illustrated containing a battery pack with a series of six connected batteries. The battery pack is for powering the electric motor of the electric golf cart. The illustration shows a wired connection between the positive end of a first voltage display to a negative end of a first battery of a battery pack. A wired connection between the negative end of the first voltage display to a positive end of the first battery of a battery pack. A wired connection between the positive end of a second voltage display to a negative end of a second battery of a battery pack. A wired connection between the negative end of a second voltage display to a positive end of a second battery of the battery pack. Electrically connecting the negative end of the first battery to the positive end of the second battery.

A wired connection between the positive end of a third voltage display to a negative end of a third battery of a battery pack. A wired connection between the negative end of a third voltage display to a positive end of a third battery of the battery pack. Electrically connecting the negative end of the second battery to the positive end of the third battery.

A wired connection between the positive end of a fourth voltage display to a negative end of a fourth battery of a battery pack. A wired connection between the negative end of a fourth voltage display to a positive end of a fourth battery of the battery pack. Electrically connecting the negative end of the third battery to the positive end of the fourth battery.

A wired connection between the positive end of a fifth voltage display to a negative end of a fifth battery of a battery pack. A wired connection between the negative end of a fifth voltage display to a positive end of a fifth battery of the battery pack. Electrically connecting the negative end of the fourth battery to the positive end of the fifth battery.

A wired connection between the positive end of a sixth voltage display to a negative end of a sixth battery of a battery pack. A wired connection between the negative end of a sixth voltage display to a positive end of a sixth battery of the battery pack. Electrically connecting the negative end of the fifth battery to the positive end of the sixth battery.

Electrically connecting a negative end of a main voltage display to a positive end of the first battery of the battery pack, and electrically connecting a positive end of a main voltage display to a negative end of a sixth battery of a battery pack. Displaying the voltage of the first battery on the first voltage display. Displaying the voltage of the second battery on the second voltage display. Displaying the voltage of the third battery on the third voltage display. Displaying the voltage of the fourth battery on the fourth voltage display. Displaying the voltage of the fifth battery on the fifth voltage display. Displaying the voltage of the sixth battery on the sixth voltage display. Displaying the voltage of the battery pack on the main voltage display.

In one embodiment, a battery pack monitor for testing the voltage of a series of batteries comprises a display panel with a plurality of voltage displays, wherein the plurality of voltage displays comprise a positive end and a negative end; a top end; an output-input port located at the top end, wherein the positive end and the negative end of the plurality of voltage displays are electrically connected to the output-input port, a wired connection with a means for connecting to the output-input port and a battery.

In one embodiment, a method of measuring the voltage of a battery pack using the battery pack monitor comprises: connecting the wired connection to the output-input port of the battery pack monitor, connecting a positive end of a first voltage display to a negative end of a first battery of a battery pack, connecting a negative end of a first voltage display to a positive end of a first battery of a battery pack, connecting a positive end of a second voltage display to a negative end of a second battery of a battery pack, connecting a negative end of a second voltage display to a positive end of a second battery of the battery pack, electrically connecting the negative end of the first battery to the positive end of the second battery, electrically connecting a negative end of a main voltage display to a positive end of the first battery of the battery pack, electrically connecting a positive end of a main voltage display to a negative end of a second battery of a battery pack, displaying the voltage of the first battery on the first voltage display, displaying the voltage of the second battery on the second voltage display, and displaying the voltage of the battery pack on the main voltage display.

All references, including publications, patent applications, and patents, cited herein are hereby incorporated by reference to the same extent as if each reference were individually and specifically indicated to be incorporated by reference and were set forth in its entirety herein.

The detailed description set forth herein in connection with the appended drawings is intended as a description of exemplary embodiments in which the presently disclosed subject matter may be practiced. The term “exemplary” used throughout this description means “serving as an example, instance, or illustration,” and should not necessarily be construed as preferred or advantageous over other embodiments.

This detailed description of illustrative embodiments includes specific details for providing a thorough understanding of the presently disclosed subject matter. However, it will be apparent to those skilled in the art that the presently disclosed subject matter may be practiced without these specific details. In some instances, well-known structures and devices are shown in block diagram form in order to avoid obscuring the concepts of the presently disclosed method and system.

The foregoing description of embodiments is provided to enable any person skilled in the art to make and use the subject matter. Various modifications to these embodiments will be readily apparent to those skilled in the art, and the novel principles and subject matter disclosed herein may be applied to other embodiments without the use of the innovative faculty. The claimed subject matter set forth in the claims is not intended to be limited to the embodiments shown herein, but is to be accorded the widest scope consistent with the principles and novel features disclosed herein. It is contemplated that additional embodiments are within the spirit and true scope of the disclosed subject matter.

1. A battery pack monitor for testing the voltage of a series of batteries comprising:
a display panel with a plurality of voltage displays, wherein the plurality of voltage displays comprise a positive end and a negative end;
a top end;
an output-input port located at the top end, wherein the positive end and the negative end of the plurality of voltage displays are electrically connected to the output-input port; and
a wired connection with a means for connecting to the output-input port and a battery.

2. The battery pack monitor of claim 1, wherein the display panel comprises 6 voltage meter displays.

3. A method of measuring the voltage of a battery pack using the battery pack monitor of claim 1, comprising:
connecting the wired connection of claim 1 to the output-input port of the battery pack monitor of claim 1;
connecting a positive end of a first voltage display to a negative end of a first battery of a battery pack;
connecting a negative end of a first voltage display to a positive end of a first battery of a battery pack;
connecting a positive end of a second voltage display to a negative end of a second battery of a battery pack;
connecting a negative end of a second voltage display to a positive end of a second battery of the battery pack;
electrically connecting the negative end of the first battery to the positive end of the second battery;
electrically connecting a negative end of a main voltage display to a positive end of the first battery of the battery pack;
electrically connecting a positive end of a main voltage display to a negative end of a second battery of a battery pack;
displaying the voltage of the first battery on the first voltage display;
displaying the voltage of the second battery on the second voltage display; and
displaying the voltage of the battery pack on the main voltage display.

4. The method of claim 3, further comprising the steps of:
connecting a positive end of a third voltage display to a negative end of a third battery of a battery pack;
connecting a negative end of a third voltage display to a positive end of a third battery of a battery pack;
displaying the voltage of the third battery on the third voltage display;
electrically connecting the negative end of the second battery to the positive end of the third battery; and
wherein the positive end of the main voltage display is connected to a negative end of a third battery of a battery pack.

5. The method of claim 4, further comprising the steps of:
connecting a positive end of a fourth voltage display to a negative end of a fourth battery of a battery pack;
connecting a negative end of a fourth voltage display to a positive end of a fourth battery of a battery pack; and
displaying the voltage of the fourth battery on the third voltage display; and
electrically connecting the negative end of the third battery to the positive end of the fourth battery; and
wherein the positive end of a main voltage display is connected to a negative end of a fourth battery of a battery pack.

6. The method of claim 5, further comprising the steps of:
connecting a positive end of a firth voltage display to a negative end of a firth battery of a battery pack;
connecting a negative end of a fifth voltage display to a positive end of a fifth battery of a battery pack; and
displaying the voltage of the fifth battery on the fifth voltage display;
electrically connecting the negative end of the fourth battery to the positive end of the fifth battery; and
wherein the positive end of the main voltage display is connected to a negative end of a fifth battery of a battery pack.

7. The method of claim 6, further comprising the steps of:
connecting a positive end of a sixth voltage display to a negative end of a sixth battery of a battery pack;
connecting a negative end of a sixth voltage display to a positive end of a sixth battery of a battery pack; and
displaying the voltage of the sixth battery on the sixth voltage display;
electrically connecting the negative end of the fifth battery to the positive end of the sixth battery; and
wherein the positive end of the main voltage display is connected to a negative end of a sixth battery of a battery pack.
